(19) United States
(12) Patent Application Publication
(10) Pub. No.: US 2016/0381795 A1
(43) Pub. Date: Dec. 29, 2016

(54) ELECTRONIC DEVICE AND METHOD FOR MANUFACTURING THE SAME

(71) Applicant: FUJITSU LIMITED, Kawasaki-shi (JP)

(72) Inventors: Junya Ikeda, Atsugi (JP); Miwa Kozawa, Atsugi (JP); Tsuyoshi Kanki, Atsugi (JP); Yoshihiro Nakata, Atsugi (JP)

(73) Assignee: FUJITSU LIMITED, Kawasaki-shi (JP)

(21) Appl. No.: 15/161,661

(22) Filed: May 23, 2016

(30) Foreign Application Priority Data
Jun. 26, 2015 (JP) 2015-128545

(51) Int. Cl. H05K 1/09; H05K 1/18; H01L 23/498; H05K 3/46; H05K 3/32; H05K 1/03; H05K 3/00

(52) U.S. Cl. CPC H05K 1/09; H05K 1/0353; H05K 1/185; H05K 3/0085; H05K 3/4661; H05K 3/32; H01L 23/49894; H01L 23/49838

(57) ABSTRACT

An electronic device includes: a substrate; a Cu-containing wiring layer formed over the substrate; a barrier metal layer that covers a surface of the Cu-containing wiring layer and suppresses diffusion of Cu; and a coating insulating layer that covers the barrier metal layer, wherein the barrier metal layer has a void that does not reach the Cu-containing wiring layer, and the void is filled with the coating insulating layer.

### CROSS-REFERENCE TO RELATED APPLICATION

This application is based upon and claims the benefit of priority of the prior Japanese Patent Application No. 2015-128545, filed on Jun. 26, 2015, the entire contents of which are incorporated herein by reference.

### FIELD

The embodiments discussed herein are related to an electronic device and a method for manufacturing the electronic device.

### BACKGROUND

In recent years, high-density interconnection used in circuit boards, fan-out wafer level packages (fan-out WLP), multi-chip packages in which a plurality of chips are connected by redistribution on a resin substrate, and the like has involved the use of fine, high-density interconnects.

For example, high-density interconnection mainly using copper interconnects may be designed so as to realize fine interconnects with a line/space of 1 μm to 5 μm. To achieve this, highly reliable interconnects are preferred.

In order to form these fine interconnects with high reliability, it has been proposed that reliability problems related to Cu-ion migration during long-time use or the like are solved by, for example, coating Cu interconnects with metal caps that are formed of NiP or the like and function as a barrier metal.

Referring to FIGS. 11A to 11D, steps of manufacturing an electronic device known in the related art will be described. First, as illustrated in FIG. 11A, for example, an adhesion layer 43, such as a Ti layer, and a Cu-plating seed layer 44 are sequentially formed on a substrate 41 by using a sputtering method or the like. The substrate 41 is provided with an underlying insulating film 42. Next, a Cu wiring layer 45 is formed by an electroplating method using a plating frame (not illustrated) formed of a photoresist.

Next, as illustrated in FIG. 11B, the exposed Cu-plating seed layer 44 is removed after removing the plating frame. Next, as illustrated in FIG. 11C, a NiP barrier metal layer 46 is formed on the surface of the Cu wiring layer 45 by, for example, an electroless plating method.

Next, as illustrated in FIG. 11D, an exposed portion of the adhesion layer 43 is selectively etched away. Next, a resin layer 47 is formed over the surface by using an epoxy resin, a polyimide resin, or a phenolic resin.

However, interconnects having a metal barrier layer formed of NiP or the like have a problem of weak adhesion to a resin insulating film in contact with the interconnects having the metal barrier layer. Such weak adhesion causes peeling at the interface between the resin insulating film and the barrier metal, for example, in reliability testing, in a heating step in reflow soldering at the time of bonding, and in high-temperature acceleration reliability testing. This peeling generates cracks in the insulating film and causes problems associated with, for example, a partial fracture of the interconnection structure.

The following is a reference document.

### [Document 1] Japanese Laid-open Patent Publication No. 2012-015405.

### SUMMARY

According to an aspect of the invention, an electronic device includes: a substrate; a Cu-containing wiring layer formed over the substrate; a barrier metal layer that covers a surface of the Cu-containing wiring layer and suppresses diffusion of Cu; and a coating insulating layer that covers the barrier metal layer, wherein the barrier metal layer has a void that does not reach the Cu-containing wiring layer, and the void is filled with the coating insulating layer.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A to 1C are explanatory diagrams illustrating an electrode structure of an electronic device in an embodiment;

FIGS. 2A to 2D are explanatory diagrams illustrating part of steps of manufacturing an electrode of an electronic device in an embodiment;

FIGS. 3A to 3C are explanatory diagrams illustrating steps of manufacturing the electrode of the electronic device in the embodiment, continued from FIG. 2D;

FIGS. 4A and 4B are explanatory graphs illustrating an operational advantage in the embodiment;

FIG. 5 is a schematic cross-sectional view of a semiconductor device in a first embodiment;

FIGS. 6A to 6C are explanatory diagrams illustrating part of steps of manufacturing the semiconductor device in the first embodiment;

FIGS. 7A to 7C are explanatory diagrams illustrating part of steps of manufacturing the semiconductor device in the first embodiment, continued from FIG. 6C;

FIGS. 8A to 8C are explanatory diagrams illustrating part of steps of manufacturing the semiconductor device in the first embodiment, continued from FIG. 7C;

FIGS. 9A to 9C are explanatory diagrams illustrating part of steps of manufacturing the semiconductor device in the first embodiment, continued from FIG. 8C;

FIGS. 10A and 10B are explanatory diagrams illustrating part of steps of manufacturing the semiconductor device in the first embodiment, continued from FIG. 9C; and

FIGS. 11A to 11D are explanatory diagrams illustrating steps of manufacturing an electrode of an electronic device known in the related art.

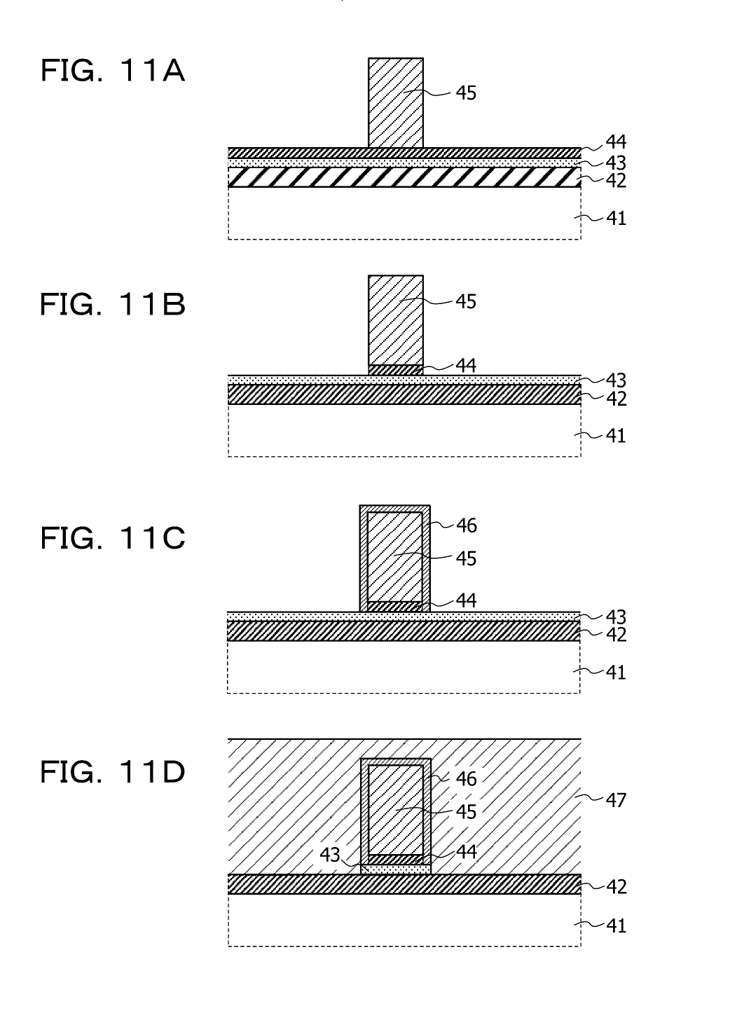

### DESCRIPTION OF EMBODIMENTS

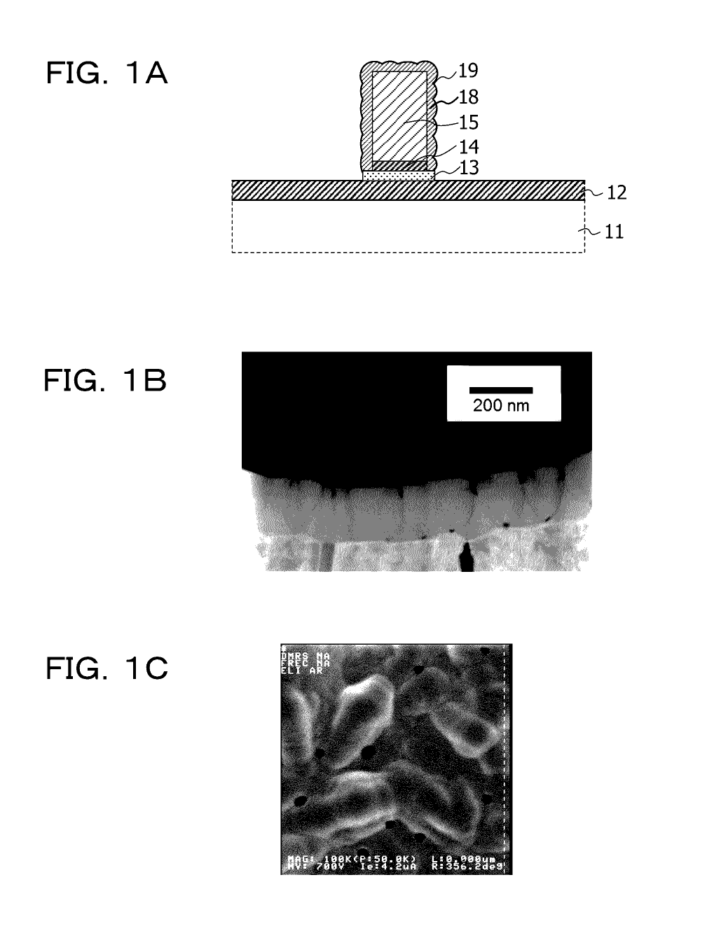

Referring to FIGS. 1A to 4B, an electronic device in an embodiment and a method for manufacturing the electronic device will be described. FIGS. 1A to 1C are explanatory diagrams illustrating an electrode structure of the electronic device in this embodiment. FIG. 1A is a schematic cross-sectional view of the electrode structure. FIG. 1B illustrates an electron microscopy image of a cross section of a barrier metal layer. FIG. 1C illustrates an electron microscopy image of the surface of the barrier metal layer.

As illustrated in FIG. 1A, the exposed surface of a Cu-containing wiring layer 15 provided over a substrate 11 with an underlying insulating film 12 therebetween is coated with a barrier metal layer 18 that suppresses diffusion of Cu. The barrier metal layer 18 has voids 19 that do not reach the Cu-containing wiring layer 15. A water-soluble-organic-substance coating film 17 is provided on at least part of the interface between the Cu-containing wiring layer 15 and the barrier metal layer 18. This water-soluble-organic-substance coating film allows the barrier metal layer 18 to grow in an island form three-dimensionally instead of two-dimensionally. When particles grow, the voids 19 are probably formed at the interfaces between adjacent grown particles as a result of the merging of the adjacent grown particles.

As illustrated in FIG. 1B and FIG. 1C, the voids 19 are found at the interfaces between the grown particles in the barrier metal layer 18. The voids have a diameter of about 5 nm to 50 nm, and the pitch between the voids is about 100 nm. Therefore, when the surface of the Cu-containing wiring layer 15 is covered with a coating resin, the coating resin enters the voids 19 formed in the barrier metal layer 18 and peeling is unlikely to occur because of the anchor effect.

Typical examples of the substrate 11 include an insulating substrate, such as a glass substrate, and a resin-coated substrate obtained by molding a resin around a printed circuit board or a semiconductor integrated circuit substrate. In the case of a glass substrate or the like, a resin insulating film is preferably provided on the surface of the glass substrate or the like. In the case of a resin-coated substrate, an electrode provided on the surface of a semiconductor integrated circuit chip is connected to the Cu-containing wiring layer 15. In this case, a Cu-containing plating layer is provided on the electrode with an adhesion layer, such as a Ti layer, and a plating seed layer formed of Cu or the like therebetween.

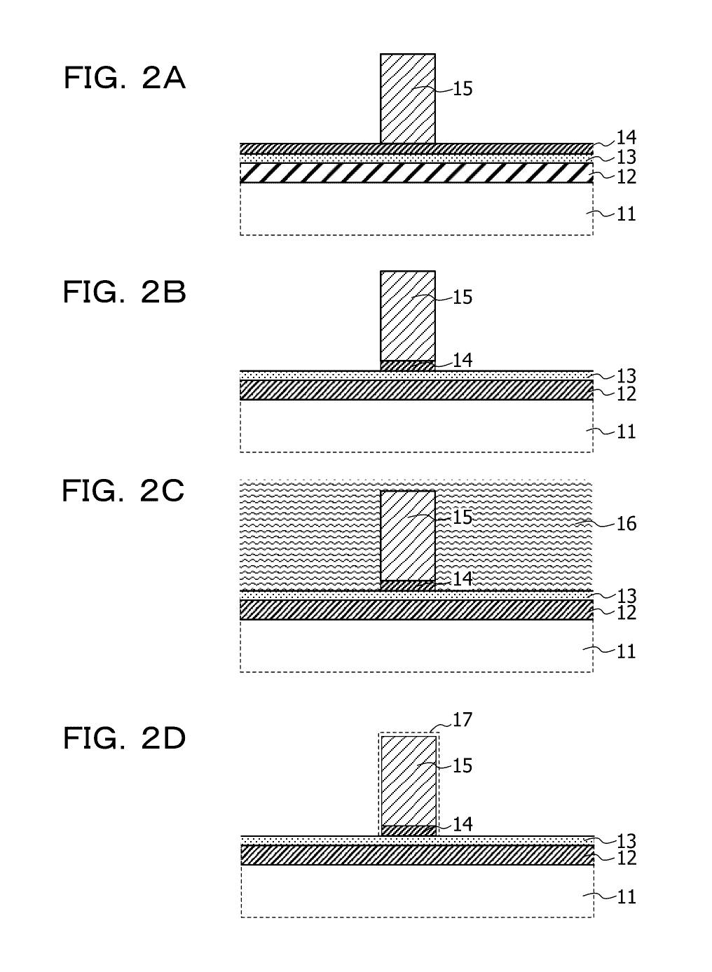

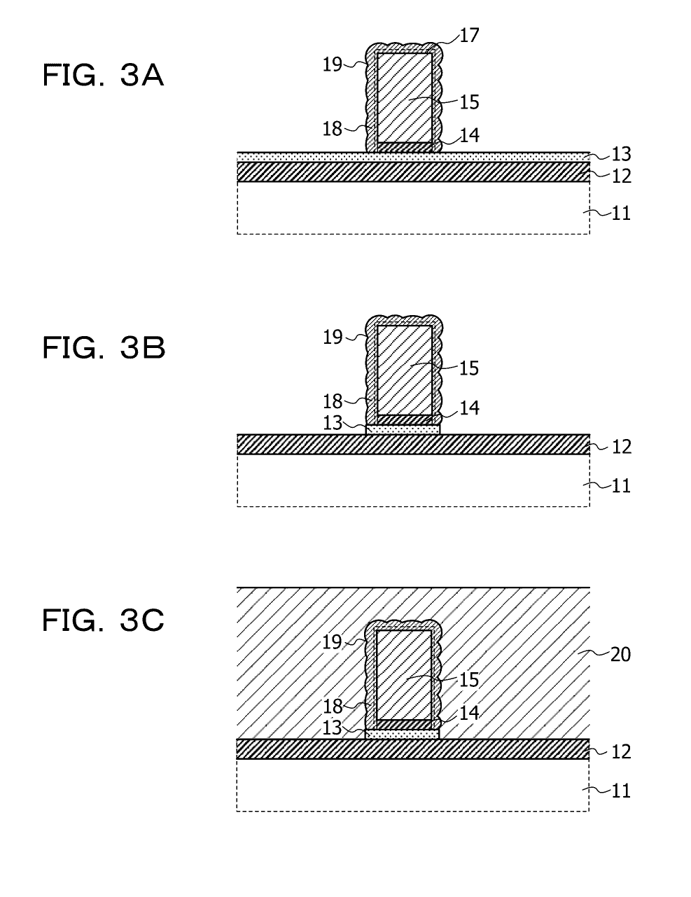

Next, referring to FIGS. 2A to 3C, steps of manufacturing an electrode of an electronic device in an embodiment will be described. First, as illustrated in FIG. 2A, for example, an adhesion layer 13, such as a Ti layer, and a plating seed layer 14 formed of Cu or the like are sequentially formed by a sputtering method or the like over a substrate 11 with an underlying insulating film 12 between the adhesion layer 13 and the substrate 11. Next, a Cu-containing wiring layer 15 is formed by an electroplating method using a plating frame (not illustrated) formed of a photoresist. A Cu wiring layer, a Si-containing Cu-based wiring layer, or the like is used as the Cu-containing wiring layer 15. The adhesion layer 13 has a thickness of, for example, about 20 nm to 30 nm. The plating seed layer 14 has a thickness of about 50 nm to 100 nm. The Cu-containing wiring layer 15 has a thickness of 1 μm to 5 μm and a width of 1 μm to 5 μm.

Next, as illustrated in FIG. 2B, the exposed plating seed layer 14 is removed after removing the plating frame. Next, as illustrated in FIG. 2C, the surface of the Cu-containing wiring layer 15 is immersed in an aqueous solution 16 containing a water-soluble organic substance at room temperature for about 3 minutes. Examples of the water-soluble organic substance in this case include glycol ethers, such as ethylene glycol monomethyl ether, ethylene glycol monoethyl ether, ethylene glycol monobutyl ether, ethylene glycol isopropyl ether, ethylene glycol dimethyl ether, ethylene glycol t-butyl ether, diethylene glycol monomethyl ether, triethylene glycol monomethyl ether, propylene glycol monomethyl ether, propylene glycol monoethyl ether, propylene glycol propyl ether, dipropylene glycol monomethyl ether, and tripropylene glycol monomethyl ether; and water-soluble resins, such as polyvinylpyrrolidone, polyvinylphenol, polyvinyl alcohol, polyacrylates, polyacrylamide, and polyethylene oxide.

When the concentration of the water-soluble organic substance in the aqueous solution 16 containing the water-soluble organic substance is 0.5 wt % to 1.0 wt %, as illustrated in FIG. 2D, the water-soluble-organic-substance coating film 17 sparsely adheres to the surface of the Cu-containing wiring layer 15. When the concentration of the water-soluble organic substance is too low, forming the water-soluble-organic-substance coating film 17 is meaningless. When the concentration of the water-soluble organic substance is too high, the water-soluble organic substance adheres to the entire surface of the Cu-containing wiring layer 15. Thus, three-dimensional growth is unlikely to occur, and no voids 19 are formed.

Next, as illustrated in FIG. 3A, a barrier metal layer 18 is formed by an electroless plating method using a Pd catalyst. Since the Pd catalyst does not adhere to Ti, the barrier metal layer 18 is formed only on the lateral sides of the plating seed layer 14 and the surface of the Cu-containing wiring layer 15. Since the water-soluble-organic-substance coating film 17 sparsely adheres to the surface of the Cu-containing wiring layer 15 in this case, the growth of the barrier metal layer 18 is partially inhibited because of the water-soluble-organic-substance coating film 17 during the film formation of the barrier metal. For this reason, particles in the metal barrier layer 18 three-dimensionally grow in an island form. When the particles grow well, voids 19 are formed at the interfaces between adjacent grown particles. These voids 19 have a diameter of about 5 nm to 50 nm. The barrier metal layer 18 has a thickness of, for example, about 50 nm to 200 nm. As the barrier metal, for example, NiP, NiWP, NiB, NiWB, CoP, CoB, CoWP, or CoWB is used.

Next, as illustrated in FIG. 3B, an exposed portion of the adhesion layer 13 is selectively etched away. At this time, for example, dry etching using CF₄ is performed. Next, as illustrated in FIG. 3C, a coating insulating layer 20 is formed over the surface by using a resin. As the coating insulating layer 20 in this case, an epoxy resin, a polyimide resin, or a phenolic resin is used.

At this time, the coating insulating layer 20 enters the voids 19 formed on the surface of the barrier metal layer 18. Consequently, the barrier metal layer 18 has increased adhesion to the coating insulating layer 20 while having a function to suppress diffusion of an interconnection material into the insulating film in reliability testing or during long-time use as in the related art.

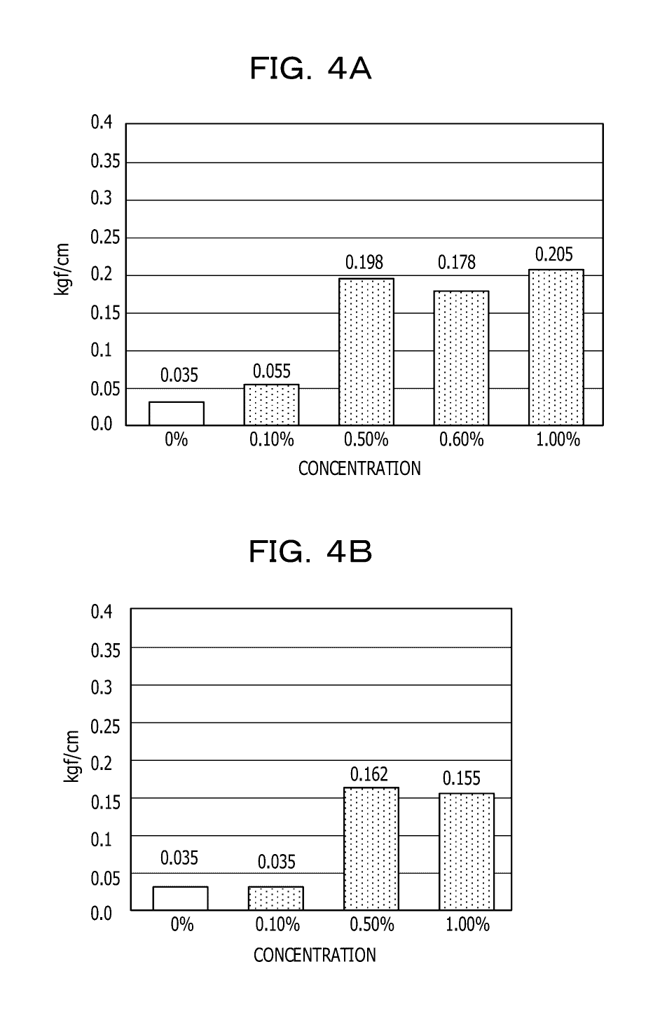

FIGS. 4A and 4B are explanatory graphs illustrating an operational advantage in this embodiment. FIG. 4A is an explanatory graph illustrating the peel strength obtained when ethylene glycol methyl ether is used as a water-soluble organic substance. FIG. 4B is an explanatory graph illustrating the peel strength obtained when polyvinylpyrrolidone is used as a water-soluble organic substance.

As illustrated in FIG. 4A, the peel strengths obtained when ethylene glycol methyl ether was used as a water-soluble organic substance were found to be higher than that obtained without immersion in the aqueous solution. In particular, the peel strengths obtained when the concentration of ethylene glycol methyl ether was 0.5 wt % to 1.0 wt % were five times or more that obtained without immersion in the aqueous solution.

As illustrated in FIG. 4B, the peel strengths obtained when polyvinylpyrrolidone was used as a water-soluble organic substance were found to be higher than that obtained without immersion in the aqueous solution. In particular, the peel strength obtained when the concentration of polyvinylpyrrolidone was 0.5 wt % to 1.0 wt % was as high as slightly less than five times that obtained without immersion in the aqueous solution.

As described above, in this embodiment, the voids 19 that do not reach the Cu-containing wiring layer 15 are formed in the barrier metal layer 18. This may improve the reliability of, for example, high-density interconnection and wafer-level packaging.

### First Embodiment

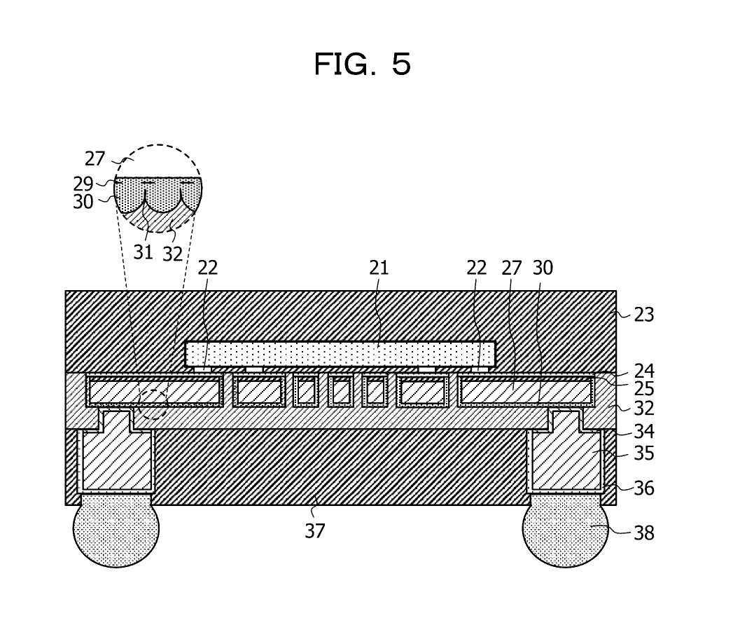

Next, referring to FIGS. 5 to 10B, a semiconductor device in a first embodiment will be described. FIG. 5 is a schematic cross-sectional view of the semiconductor device in the first embodiment. A resin-coated semiconductor chip is obtained by molding a mold resin around a semiconductor integrated circuit chip 21 provided with chip-side electrodes 22. A Cu wiring layer 27 is formed under the resin-coated semiconductor chip by high-density interconnection as in the related art. Cu pads 35 are formed under the Cu wiring layer 27, and solder balls 38 are transferred to the Cu pads 35, followed by mounting on a target substrate.

In the first embodiment, the Cu wiring layer 27 is coated with a NiP barrier metal layer 30 having voids 31, and a resin layer 32 is then formed by attaching an epoxy resin film to the entire surface. A glycol-ether coating film 29 is formed at the interface between with the Cu wiring layer 27 and the NiP barrier metal layer 30.

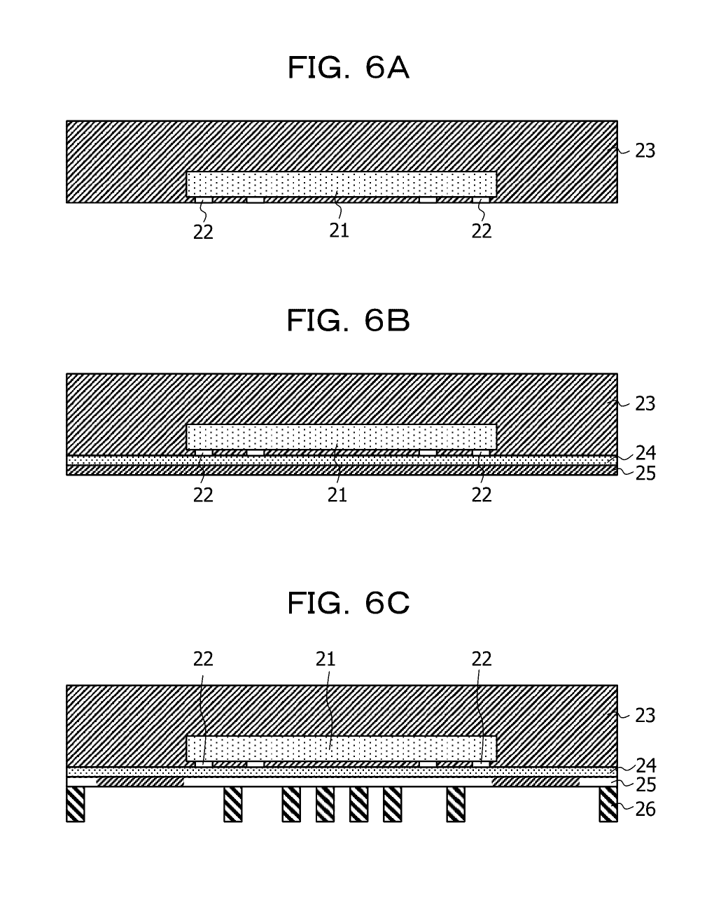

Next, referring to FIGS. 6A to 10B, steps of manufacturing the semiconductor device in the first embodiment will be described. First, as illustrated in FIG. 6A, a resin-coated semiconductor chip in which a semiconductor integrated circuit chip 21 provided with chip-side electrodes 22 is surrounded with a mold resin 23 is provided. Next, as illustrated in FIG. 6B, a Ti adhesion layer 24 having a thickness of 20 nm and a Cu-plating seed layer 25 having a thickness of 100 nm are sequentially formed by using a sputtering method.

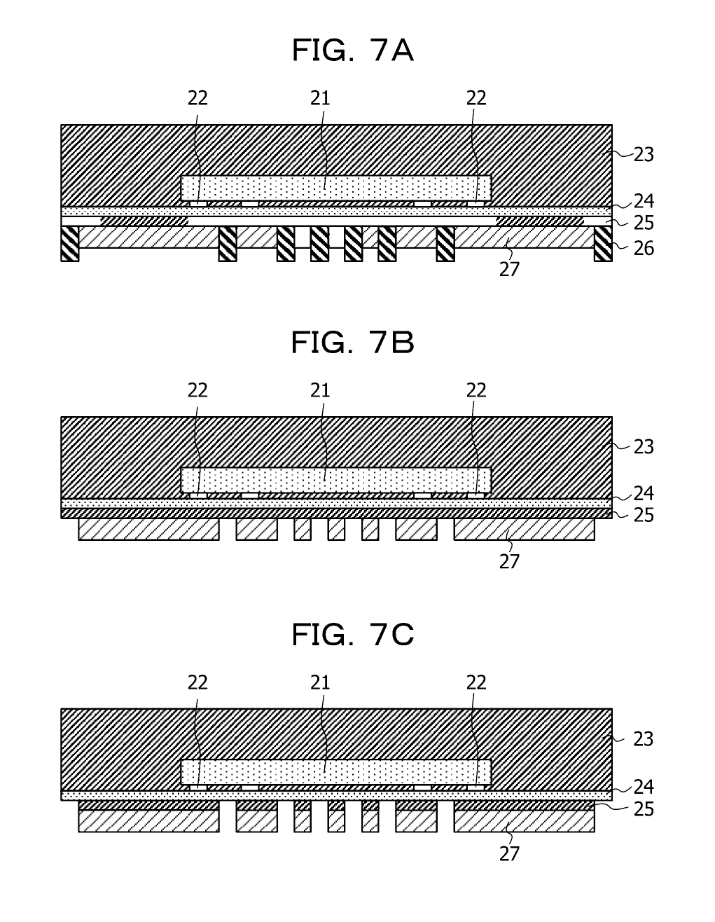

Next, as illustrated in FIG. 6C, a plating frame 26 is formed by applying a photoresist, exposing the photoresist to light so as to form a predetermined interconnection pattern, and developing the photoresist. Next, as illustrated in FIG. 7A, a Cu wiring layer 27 having a thickness of 3 μm and a width of 3 μm is formed by using the plating frame 26 as a mask.

Next, as illustrated in FIG. 7B, the plating frame 26 is removed. Next, as illustrated in FIG. 7C, exposed portions of the Cu-plating seed layer 25 are removed by wet etching using Melstrip CU-3930 (product name, available from Meltex Inc.).

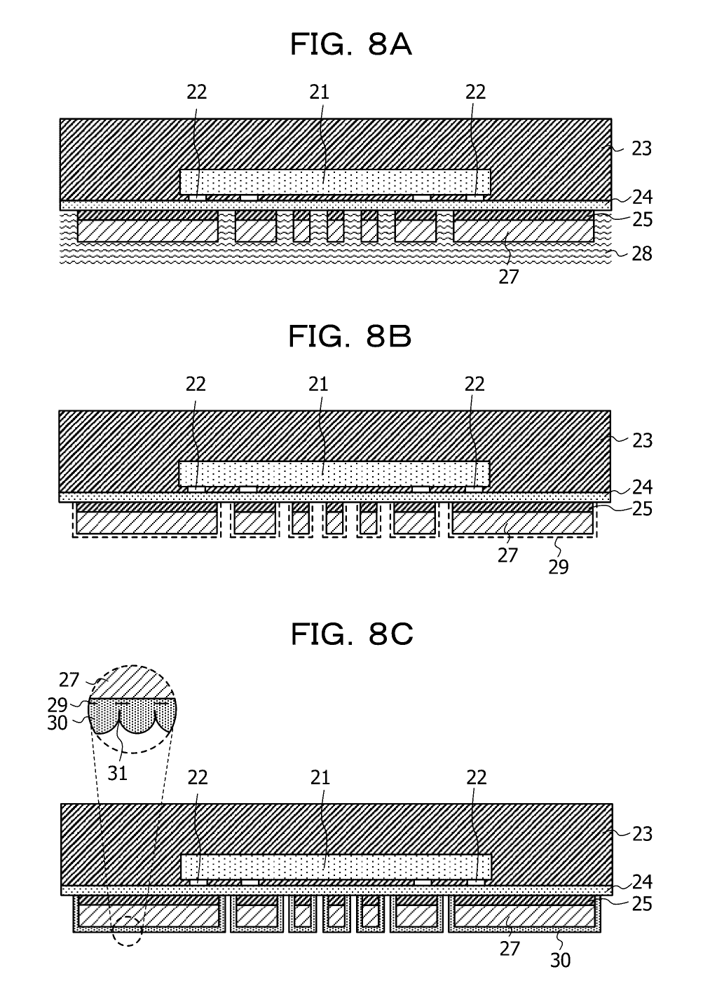

Next, as illustrated in FIG. 8A, the resultant product is immersed in a 1.0% aqueous solution of a glycol ether at room temperature for 3 minutes. In this case, ethylene glycol methyl ether is used as a glycol ether. At this time, as illustrated in FIG. 8B, a glycol-ether coating film 29 is sparsely formed on the surface of the Cu wiring layer 27.

Next, as illustrated in FIG. 8C, a NiP barrier metal layer 30 having a thickness of 100 nm is formed by an electroless plating method using Pd as a catalyst. At this time, voids 31 that have a diameter of about 5 nm to 50 nm and do not reach the Cu wiring layer 27 are formed on the NiP barrier metal layer 30. Since the Pd catalyst does not adhere to Ti, the NiP barrier metal layer 30 is formed only on the Cu surface.

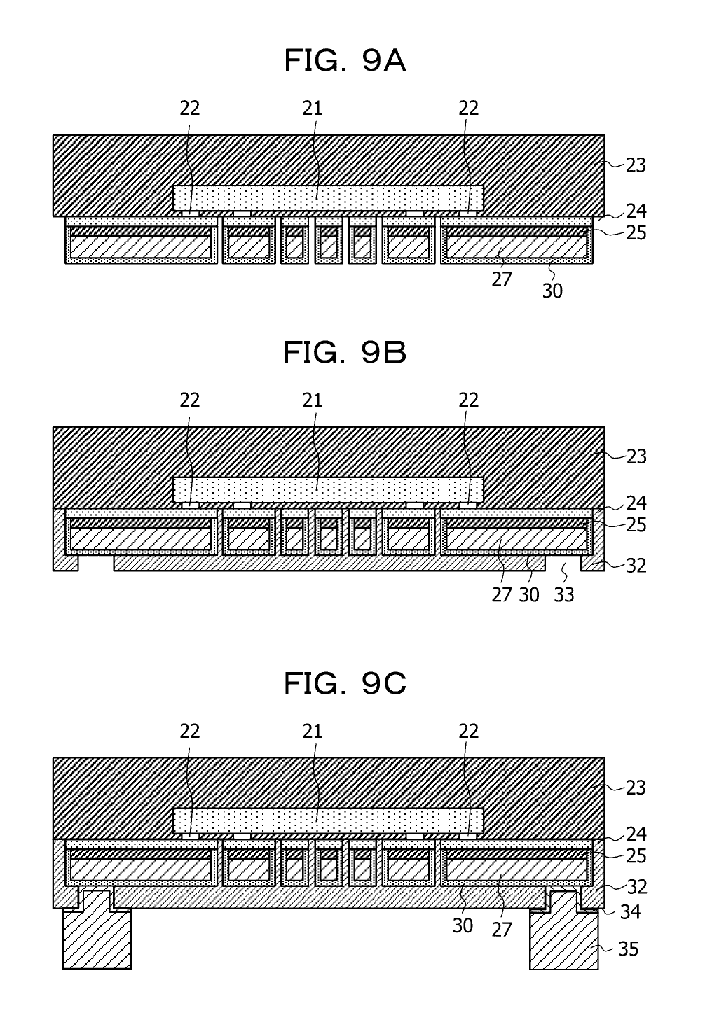

Next, as illustrated in FIG. 9A, exposed portions of the Ti adhesion layer 24 are selectively removed by dry etching using CF₄. Next, as illustrated in FIG. 9B, an epoxy resin film having a thickness of 10 μm is stacked to form a resin layer 32. Next, openings 33 in communication with the Cu wiring layer 27 are formed.

Next, as illustrated in FIG. 9C, a Cu-plating seed layer 34 having a thickness of 100 nm is formed by a sputtering method. A Cu-plating layer having a thickness of 30 μm is then formed by an electroplating method using a plating frame (not illustrated) as a mask. Next, after removing the plating frame, Cu pads 35 are formed by removing exposed portions of the Cu-plating seed layer 34.

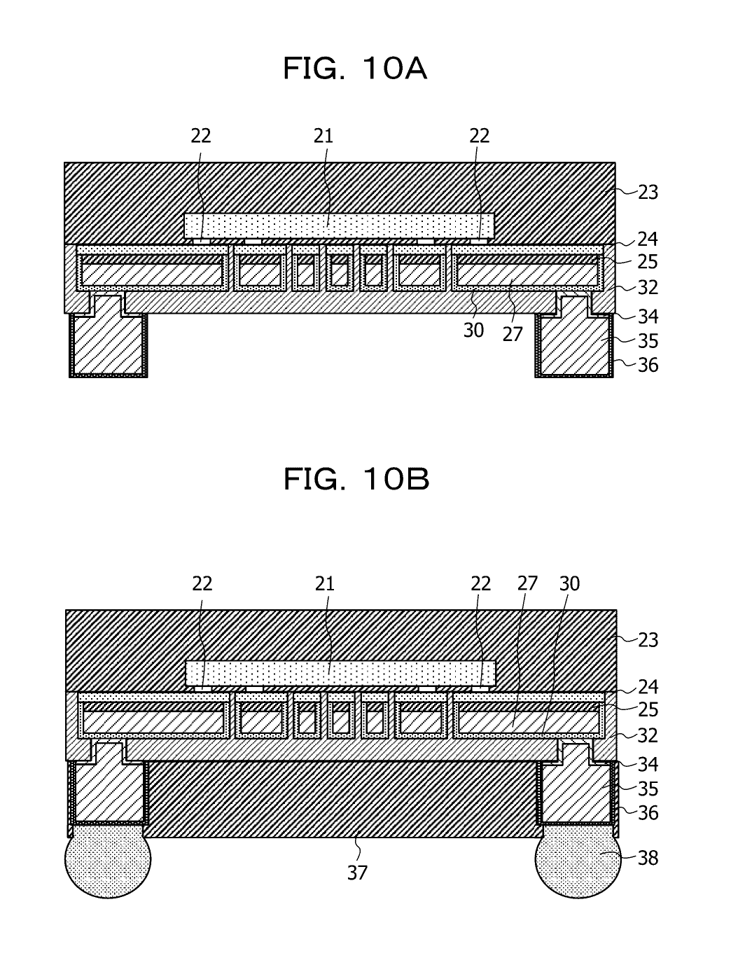

Next, as illustrated in FIG. 10A, a NiAu barrier metal layer 36 having a thickness of 100 nm is selectively formed on the exposed lateral sides of the Cu-plating seed layer 34 and on the surfaces of the Cu pads 35 by an electroless plating method using Pd as a catalyst.

Next, as illustrated in FIG. 10B, a resin layer 37 having a thickness of 50 μm is formed by applying a phenolic resin to the entire surface. Next, openings in communication with the Cu pads 35 are formed and then solder balls 38 are transferred to the openings. Consequently, the basic structure of the semiconductor device in the first embodiment is completed. Thereafter, this semiconductor device will be mounted on a target substrate.

In the first embodiment, the fine voids 31 that do not reach the Cu wiring layer 27 are formed in the NiP barrier metal layer 30 when high-density interconnection is formed in the mounting of the resin-coated semiconductor device. Such formation of the fine voids 31 significantly improves the adhesion to the resin layer 32. Therefore, even if a barrier metal layer having low adhesion to the resin layer is formed in order to suppress diffusion of the interconnection material into the insulating film, peeling is unlikely to occur in reliability testing or during long-time use.

Although high-density interconnection is formed on the resin-coated semiconductor chip in the first embodiment, high-density interconnection is not necessarily formed on the resin-coated semiconductor chip and may be alternatively formed on a circuit board or a glass substrate. In the latter cases, the adhesion of a wiring layer to a coating insulating layer is also improved by forming a metal barrier layer having voids on the surface and, as a result, the reliability of a high-density interconnection structure increases.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
a substrate;
a Cu-containing wiring layer formed over the substrate;
a barrier metal layer that covers a surface of the Cu-containing wiring layer and suppresses diffusion of Cu; and
a coating insulating layer that covers the barrier metal layer,
wherein the barrier metal layer has a void that does not reach the Cu-containing wiring layer, and the void is filled with the coating insulating layer.

2. The electronic device according to claim 1,
wherein an organic-substance coating film is provided on at least part of an interface between the Cu-containing wiring layer and the barrier metal layer, and
the void is formed at an interface between grown particles in the barrier metal layer.

3. The electronic device according to claim 2,
wherein the organic-substance coating film is a coating film formed of any one of a glycol ether and a water-soluble resin.

4. The electronic device according to claim 3,
wherein the glycol ether is any one of ethylene glycol monomethyl ether, ethylene glycol monoethyl ether, ethylene glycol monobutyl ether, ethylene glycol isopropyl ether, ethylene glycol dimethyl ether, ethylene glycol t-butyl ether, diethylene glycol monomethyl ether, triethylene glycol monomethyl ether, propylene glycol monomethyl ether, propylene glycol monoethyl ether, propylene glycol propyl ether, dipropylene glycol monomethyl ether, and tripropylene glycol monomethyl ether.

5. The electronic device according to claim 3,
wherein the water-soluble resin is any one of polyvinylpyrrolidone, polyvinylphenol, polyvinyl alcohol, polyacrylates, polyacrylamide, and polyethylene oxide.

6. The electronic device according to claim 1,
wherein the void has a diameter of 5 nm to 50 nm.

7. The electronic device according to claim 1,
wherein the substrate is a resin-coated substrate in which a semiconductor integrated circuit chip is surrounded with a mold resin, and
the Cu-containing wiring layer is in contact with an electrode provided over the semiconductor integrated circuit chip.

8. The electronic device according to claim 7,
wherein the electrode is in contact with the Cu-containing wiring layer with an adhesion layer and a plating seed layer therebetween, the adhesion layer and the plating seed layer being formed on the surface of the substrate.

9. A method for manufacturing an electronic device, comprising:
forming a Cu-containing wiring layer over a substrate;
immersing a surface of the Cu-containing wiring layer in an aqueous solution containing a water-soluble organic substance;
coating an exposed surface of the Cu-containing wiring layer with a barrier metal layer by an electroless plating method, the Cu-containing wiring layer being obtained after immersion in the aqueous solution, the barrier metal layer suppressing diffusion of Cu; and
coating a surface of the barrier metal layer with a coating insulating layer.

10. The method for manufacturing an electronic device according to claim 9,
wherein the water-soluble organic substance is any one of a glycol ether and a water-soluble resin.

11. The method for manufacturing an electronic device according to claim 10,
wherein the glycol ether is any one of ethylene glycol monomethyl ether, ethylene glycol monoethyl ether, ethylene glycol monobutyl ether, ethylene glycol isopropyl ether, ethylene glycol dimethyl ether, ethylene glycol t-butyl ether, diethylene glycol monomethyl ether, triethylene glycol monomethyl ether, propylene glycol monomethyl ether, propylene glycol monoethyl ether, propylene glycol propyl ether, dipropylene glycol monomethyl ether, and tripropylene glycol monomethyl ether.

12. The method for manufacturing an electronic device according to claim 10,
wherein the water-soluble resin is any one of polyvinylpyrrolidone, polyvinylphenol, polyvinyl alcohol, polyacrylates, polyacrylamide, and polyethylene oxide.

13. The method for manufacturing an electronic device according to claim 11,
wherein a concentration of the water-soluble organic substance in the aqueous solution is 0.5 wt % to 1.0 wt %.

14. The method for manufacturing an electronic device according to claim 9,
wherein the forming the Cu-containing wiring layer over the substrate includes:
forming an adhesion layer on a resin-coated semiconductor chip in which a semiconductor integrated circuit chip is surround with a mold resin, the semiconductor integrated circuit chip having an electrode on a surface of the semiconductor integrated circuit chip on which the Cu-containing wiring layer is to be formed;
forming a plating seed layer on the adhesion layer; and
forming a Cu-containing plating layer on the plating seed layer by electrolytic plating.
